(19) United States
(12) Patent Application Publication
(10) Pub. No.: US 2026/0018864 A1
(43) Pub. Date: Jan. 15, 2026

(54) VERTICAL CAVITY SURFACE EMITTING LASER DEVICE AND VERTICAL CAVITY SURFACE EMITTING LASER DEVICE ARRAY

(71) Applicant: Sony Semiconductor Solutions Corporation, Kanagawa (JP)

(72) Inventor: Takahiro ARAKIDA, Miyagi (JP)

(21) Appl. No.: 18/862,431

(22) PCT Filed: May 18, 2023
(86) PCT No.: PCT/JP2023/018567

§ 371 Date: Sep. 11, 2025

(30) Foreign Application Priority Data
Jun. 13, 2022 (JP) 2022-095089

(51) Int. Cl. H01S 5/183; H01S 5/323; H01S 5/42

(52) U.S. Cl. CPC H01S 5/18361; H01S 5/18305; H01S 5/32308; H01S 5/423

(57) ABSTRACT

[Object] To provide a vertical cavity surface emitting laser device and a vertical cavity surface emitting laser device array that use a GaAs substrate and have excellent light emission efficiency and reliability.

[Solving Means] A vertical cavity surface emitting laser device according to the present technology includes: a substrate; and a light-emitting unit. The substrate is formed of InₓGa₁₋ₓAs (x is 0.005 or more and 0.015 or less) and has a carrier concentration of less than 5×10¹⁷/cm³. The light-emitting unit includes a first distributed Bragg reflector (DBR) that is formed on the substrate and reflects light having a specific wavelength, a second DBR that reflects light having the wavelength, and an active region that is disposed between the first DBR and the second DBR and generates light emission due to carrier recombination.

### TECHNICAL FIELD

The present technology relates to a vertical cavity surface emitting laser device and a vertical cavity surface emitting laser device array that emit laser light in a direction perpendicular to a layer surface.

### BACKGROUND ART

A vertical cavity surface emitting laser (VCSEL) device has a structure in which an active region that generates light emission is sandwiched between a pair of distributed Bragg reflectors (DBRs). A current confinement structure is provided in the vicinity of the active region, and the current confinement structure concentrates the current in part of the active region, generating spontaneous emission light. The pair of DBRs reflects light having a predetermined wavelength, of the spontaneous emission light, toward the active region, thereby generating laser oscillation.

Since the VCSEL device is formed on the substrate by epitaxial growth using a metal organic chemical vapor deposition (MOCVD) method, it is necessary to select the substrate material in accordance with the light emission wavelength. A general substrate material of the VCSEL device is GaAs (gallium arsenide), and an n-type GaAs substrate or semi-insulating GaAs is often used. As a substrate material of the VCSEL device, the application of an InGaAs (indium gallium arsenide) substrate is also known as described in the following Patent Literature 1.

### CITATION LIST

### Patent Literature

Patent Literature 1: Japanese Patent Application Laid-open No. 2007-66930

### DISCLOSURE OF INVENTION

### Technical Problem

The VCSEL device includes a back-illuminated VCSEL device in which a laser beam is transmitted through a substrate and is emitted and a front-illuminated VCSEL device in which a laser beam is emitted on the side opposite to the substrate. In the VCSEL including an AlGaAs DBR layer, it is important to reduce the warping on the substrate in the production process. Further, when an n-type GaAs substrate or an n-type InGaAs substrate is used in the back-emitting VCSEL device, there is a problem that when a laser beam is transmitted through the substrate, light absorption occurs due to free carriers of the n-type substrate and the light emission efficiency is reduced.

In view of the circumstances as described above, it is an object of the present technology to provide a vertical cavity surface emitting laser device and a vertical cavity surface emitting laser device array that use an InGaAs substrate and have excellent light emission efficiency and reliability.

### Solution to Problem

In order to achieve the above-mentioned object, a vertical cavity surface emitting laser device according to an embodiment of the present technology includes: a substrate; and a light-emitting unit.

The substrate is formed of InₓGa₁₋ₓAs (x is 0.005 or more and 0.015 or less) and has a carrier concentration of less than 5×10¹⁷/cm³.

The light-emitting unit includes a first distributed Bragg reflector (DBR) that is formed on the substrate and reflects light having a specific wavelength, a second DBR that reflects light having the wavelength, and an active region that is disposed between the first DBR and the second DBR and generates light emission due to carrier recombination.

A lattice constant of the substrate may be a value between a lattice constant of GaAs and a lattice constant of AlAs.

The lattice constant of the substrate may be larger than 5.6533 Å and smaller than 5.6605 Å.

The first DBR and the second DBR may each be formed of n-type or p-type AlGaAs, and the active region may include an active layer formed of InGaAs.

The vertical cavity surface emitting laser device may be a back-emitting device in which a laser beam travels from the light-emitting unit to a side of the substrate, is transmitted through the substrate, and is emitted.

The vertical cavity surface emitting laser device may be a front-emitting device in which a laser beam travels from the light-emitting unit to a side opposite to the substrate and is emitted on the side opposite to the substrate.

The light-emitting unit may include a pair of electrodes disposed such that a current is injected into the active region without passing through the substrate.

The light-emitting unit may include a first contact layer that abuts on the first DBR and a second contact layer that abuts on the second DBR, and the pair of electrodes may include a first electrode provided on the first contact layer and a second electrode provided on the second contact layer.

In order to achieve the above-mentioned object, a vertical cavity surface emitting laser device array according to an embodiment of the present technology includes: a substrate; and a plurality of light-emitting units.

The substrate is formed of InₓGa₁₋ₓAs (x is 0.005 or more and 0.015 or less) and has a carrier concentration of less than 5×10¹⁷/cm³.

The plurality of light-emitting units is a plurality of light-emitting units formed on the substrate, each of the light-emitting units including a first distributed Bragg reflector (DBR) that reflects light having a specific wavelength, a second DBR that reflects light having the wavelength, and an active region that is disposed between the first DBR and the second DBR and generates light emission due to carrier recombination.

### BRIEF DESCRIPTION OF DRAWINGS

FIG. 1 is a cross-sectional view of a back-emitting VCSEL device according to an embodiment of the present technology.

FIG. 2 is a schematic diagram showing an operation of the VCSEL device.

FIG. 3 is a cross-sectional view of a back-emitting VCSEL device array according to an embodiment of the present technology.

FIG. 4 is a schematic diagram showing a method of producing the VCSEL device array.

FIG. 5 is a schematic diagram showing a method of producing the VCSEL device array.

FIG. 6 is a schematic diagram showing a method of producing the VCSEL device array.

FIG. 7 is a schematic diagram showing a method of producing the VCSEL device array.

FIG. 8 is a cross-sectional view of a front-emitting VCSEL device according to an embodiment of the present technology.

FIG. 9 is a cross-sectional view of a front-emitting VCSEL device according to an embodiment of the present technology.

FIG. 10 is a cross-sectional view of a front-emitting VCSEL device array according to an embodiment of the present technology.

### MODE(S) FOR CARRYING OUT THE INVENTION

A vertical cavity surface emitting laser (VCSEL) device according to an embodiment of the present technology will be described.

### [Structure of VCSEL Device]

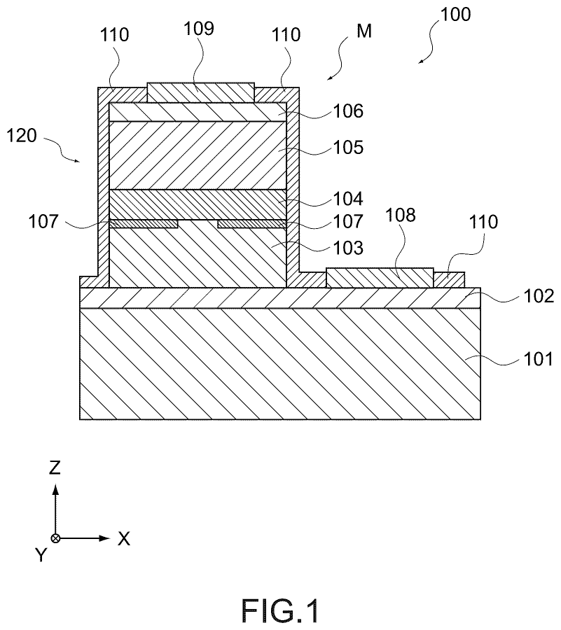

FIG. 1 is a cross-sectional view of a VCSEL device 100 according to this embodiment. As shown in the figure, the VCSEL device 100 includes a substrate 101, a first contact layer 102, a first DBR 103, an active region 104, a second DBR 105, a second contact layer 106, a current confinement portion 107, a first electrode 108, a second electrode 109, and a dielectric film 110.

Of these, the first DBR 103, the active region 104, the second DBR 105, and the second contact layer 106 form a mesa (plateau) structure M.

Hereinafter, the oscillation wavelength of the VCSEL device 100 will be referred to as a wavelength A. Further, in the following figures, a layer surface direction of each layer forming the VCSEL device 100 will be referred to as an X-Y direction and a direction perpendicular to the layer surface direction will be referred to as a Z direction.

The substrate 101 supports each layer of the VCSEL device 100. The material of the substrate 101 will be referred to as a “substrate material”. The substrate material is InₓGa₁₋ₓAs (x is 0.005 or more and 0.015 or less) and has a carrier concentration of less than 5×10¹⁷/cm³. The carrier concentration of less than 5×10¹⁷/cm³ is significantly smaller than the carrier concentrations of a general n-type substrate and a general p-type substrate.

Further, the substrate material may include one or more types of dopants such as Si, C, and Zn. Further, in the case where the substrate material includes these dopants, the substrate material only needs to have a carrier concentration of In and another dopant of less than 5×10¹⁷/cm³.

Further, the substrate material suitably has a lattice constant of a value between a lattice constant of GaAs and a lattice constant of AlAs. Since the lattice constant of GaAs is 5.6533 Å and the lattice constant of AlAs is 5.6605 Å, the lattice constant of the substrate material is suitably a value that is larger than 5.6533 Å and smaller than 5.6605 Å. The lattice constant of the substrate material can be adjusted by the amount of In. For example, when the composition ratio of In to As is 0.5% or more and 1.5% or less, the lattice constant of the substrate material is a value between the lattice constants of GaAs and AlAs.

The first contact layer 102 is provided on the substrate 101 and abuts on the first DBR 103 and the first electrode 108 to electrically connect them. The first contact layer 102 is formed of a p-type semiconductor material and is formed of, for example, p-GaAs having a carrier concentration of 3×10¹⁹/cm³.

The first DBR 103 is provided on the first contact layer 102, reflects light having the wavelength λ, and causes light having a wavelength other than that to be transmitted therethrough. The first DBR 103 is a distributed Bragg reflector (DBR) obtained by alternately stacking a low-refractive index layer and a high-refractive index layer having an optical film thickness of λ/4 to form a plurality of layers. The first DBR 103 is a p-DBR formed of a p-type semiconductor material and includes, for example, p-AlGaAs layers having different Al compositions.

The active region 104 is provided on the first DBR 103 and emits and amplifies spontaneous emission light due to carrier recombination.

Specifically, the active region 104 includes an active layer, a barrier layer, and a guide layer. The active region 104 is configured in accordance with the oscillation wavelength λ and application of the VCSEL device 100. For example, the oscillation wavelength A can be set to a 900 nm band by combining an active layer formed of InGaAs and a barrier layer formed of AlGaAs.

The second DBR 105 is provided on the active region 104, reflects light having the wavelength λ, and causes light having a wavelength other than that to be transmitted therethrough. The second DBR 105 is a distributed Bragg reflector (DBR) obtained by alternately stacking a low-refractive index layer and a high-refractive index layer having an optical film thickness of λ/4 to form a plurality of layers. The second DBR 105 is an n-DBR formed of an n-type semiconductor material and includes, for example, n-AlGaAs layers having different Al compositions.

The second contact layer 106 is provided on the second DBR 105 and abuts on the second DBR 105 and the second electrode 109 to electricity connect them. The second contact layer 106 is formed of an n-type semiconductor material and is formed of, for example, n-GaAs having a carrier concentration of 3×10¹⁸/cm³.

The current confinement portion 107 is provided in the first DBR 103 and confines the injected current. The current confinement portion 107 is a portion insulated by oxidation and is provided except for the central portion of the mesa structure M. Specifically, the current confinement portion 107 is provided by oxidizing the AlGaAs layer or the AlAs layer having a high Al composition provided in the first DBR 103 from the outer periphery side of the mesa structure M and is formed of, for example, Al₂O₃.

The first electrode 108 is provided on the first contact layer 102 and functions as one electrode of the VCSEL device 100. In the case where the first electrode 108 is a p-electrode, it is formed of Ti/Pt/Au, or the like. In the case where the first electrode 108 is an n-electrode, it is formed of AuGe/Ni/Au, or the like. The second electrode 109 is provided on the second contact layer 106 and functions as the other electrode of the VCSEL device 100. In the case where the second electrode 108 is a p-electrode, it is formed of Ti/Pt/Au, or the like. In the case where the second electrode 108 is an n-electrode, it is formed of a metal such as AuGe/Ni/Au. The first electrode 108 and the second electrode 109 are disposed such that a current is injected into the active region 104 without passing through the substrate 101. The dielectric film 110 covers the surfaces of the first contact layer 102 and the mesa structure M except for the first electrode 108 and the second electrode 109. The dielectric film 110 is formed of, for example, SiNₓ.

The VCSEL device 100 has a configuration as described above. Of the above configuration, the first contact layer 102, the first DBR 103, the active region 104, the second DBR 105, the second contact layer 106, the current confinement portion 107, the first electrode 108, and the second electrode 109 will be collectively referred to as a light-emitting unit 120. That is, the VCSEL device 100 is configured by forming the light-emitting unit 120 on the substrate 101.

Note that although the side of the first DBR 103 is a p-type and the side of the second DBR 105 is an n-type in the VCSEL device 100 in the above description, the p-type and the n-type may be reversed. Further, although the VCSEL device 100 includes the current confinement portion 107 having an oxidized confinement structure in the above description, it may have another current confinement structure such as ion implantation and a buried tunnel junction. In addition, the VCSEL device 100 only needs to include the above-mentioned substrate 101 and have a configuration capable of emitting a laser beam.

### [Operation of VCSEL Device]

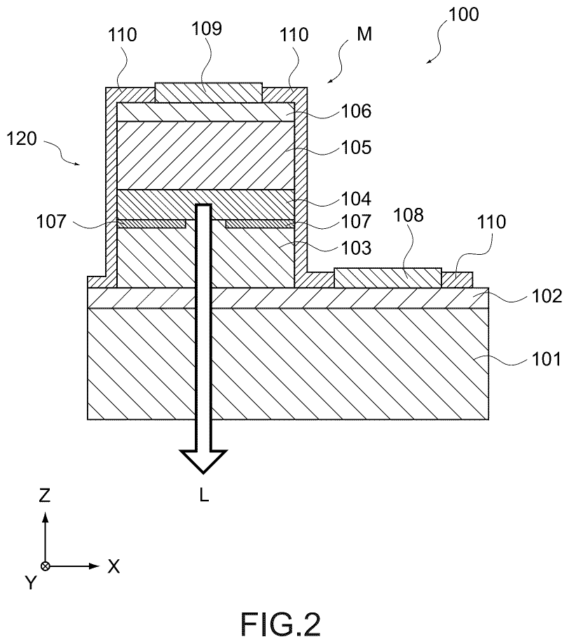

FIG. 2 is a schematic diagram of an operation of the VCSEL device 100. When a voltage is applied between the first electrode 108 and the second electrode 109, a current flows between the first electrode 108 and the second electrode 109. Here, the current confinement portion 107 is provided in the vicinity of the active region 104, and a current concentrates in the center of the mesa structure M and is injected into the active region 104. Note that since the substrate 101 has a low carrier concentration, the conductivity thereof is low. This is not a problem because the first electrode 108 and the second electrode 109 are disposed such that a current is injected into the active region 104 without passing through the substrate 101.

This current injection generates spontaneous emission light due to carrier recombination in the active region 104. The spontaneous emission light travels in the stacking direction of the VCSEL device 100 (Z direction) and is reflected by the first DBR 103 and the second DBR 105. Since the first DBR 103 and the second DBR 105 are configured to reflect light having the oscillation wavelength A, the component of the spontaneous emission light having the oscillation wavelength λ forms a standing wave between the first DBR 103 and the second DBR 105 and is amplified by the active region 104. When the injected current exceeds a threshold value, the light forming a standing wave causes laser oscillation and is transmitted through the first DBR 103, and a laser beam L is emitted from the light-emitting unit 120. The laser beam L travels from the light-emitting unit 120 to the side of the substrate 101, is transmitted through the substrate 101, and is emitted. Note that the VCSEL device in which a laser beam is emitted to the substrate side as described above is referred to as a back-emitting VCSEL device.

### [Effects of VCSEL Device]

The VCSEL device 100 includes the substrate 101 formed of a substrate material that is InₓGa₁₋ₓAs (x is 0.005 or more and 0.015 or less) and has a carrier concentration of less than 5×10¹⁷/cm³ as described above. Since the carrier concentration of the substrate material is small, i.e., 5×10¹⁷/cm³, the light absorption by free carriers in the substrate 101 is suppressed, and the laser beam L transmitted through the substrate 101 is not attenuated. Therefore, the VCSEL device 100 has high light emission efficiency.

Further, since the presence of In suppresses crystal defects in GaAs, the substrate 101 has a low crystal defect density. For this reason, crystal defects in each layer formed on the substrate 101 by epitaxial growth are also suppressed, and the VCSEL device 100 has high reliability. Note that even in the case where the substrate material is doped with a dopant, it is possible to reduce crystal defects in GaAs by setting the amount of In to 0.01% or more in terms of In composition.

In addition, by setting the lattice constant of the substrate material to a value between the lattice constant of GaAs and the lattice constant of AlAs, lattice distortion occurring mainly in the DBR layer is reduced, and warping of the epitaxial wafer is reduced in the process of producing the VCSEL device 100. When the wafer is warped, the process processing accuracy deteriorates and the productivity deteriorates due to a decrease in yield or the like. However, in the VCSEL device 100, it is possible to reduce the warping of the wafer and improve the productivity.

### [Regarding VCSEL Device Array]

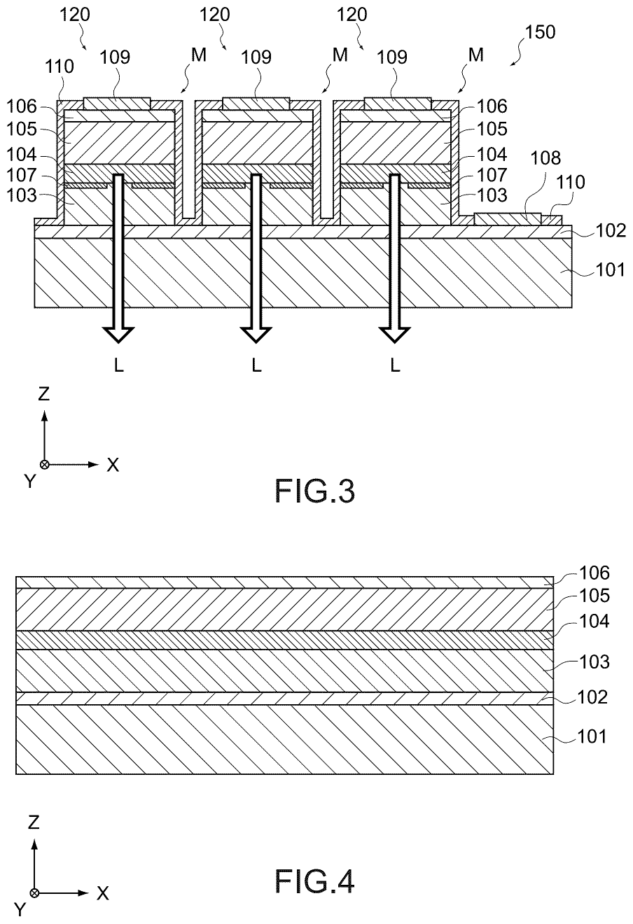

The VCSEL device 100 may constitute an array. FIG. 3 is a cross-sectional view of a VCSEL device array 150 according to this embodiment. As shown in the figure, the VCSEL device array 150 includes one substrate 101 and a plurality of light-emitting units 120 formed thereon. The configurations of the substrate 101 and the light-emitting unit 120 are the same as those in the VCSEL device 100, and the laser beam L is transmitted through the substrate 101 and emitted from each light-emitting unit 120. The number and arrangement of the light-emitting units 120 are not particularly limited, and a one-dimensional array or a two-dimensional array may be used. The VCSEL device array 150 also provides the same effects as those of the VCSEL device 100.

### [Method of Producing VCSEL Device Array]

A method of producing the VCSEL device array 150 will be described. FIG. 4 to FIG. 7 are each a schematic diagram showing a method of producing the VCSEL device array 150.

First, the substrate 101 is prepared. The substrate 101 can be prepared by doping GaAs crystals with In or another dopant when growing the GaAs crystals by a crystal growth method such as a horizontal Bridgman (HB) method. Subsequently, as shown in FIG. 4, the first contact layer 102, the first DBR 103, the active region 104, the second DBR 105, and the second contact layer 106 are stacked on the substrate 101. Each of these layers can be stacked by epitaxial growth on the substrate 101 by a metal organic chemical vapor deposition (MOCVD) method.

Subsequently, as shown in FIG. 5, the first DBR 103, the active region 104, the second DBR 105, and the second contact layer 106 are patterned to form the mesa structure M. This patterning can be performed by photolithography and reactive ion etching (RIE).

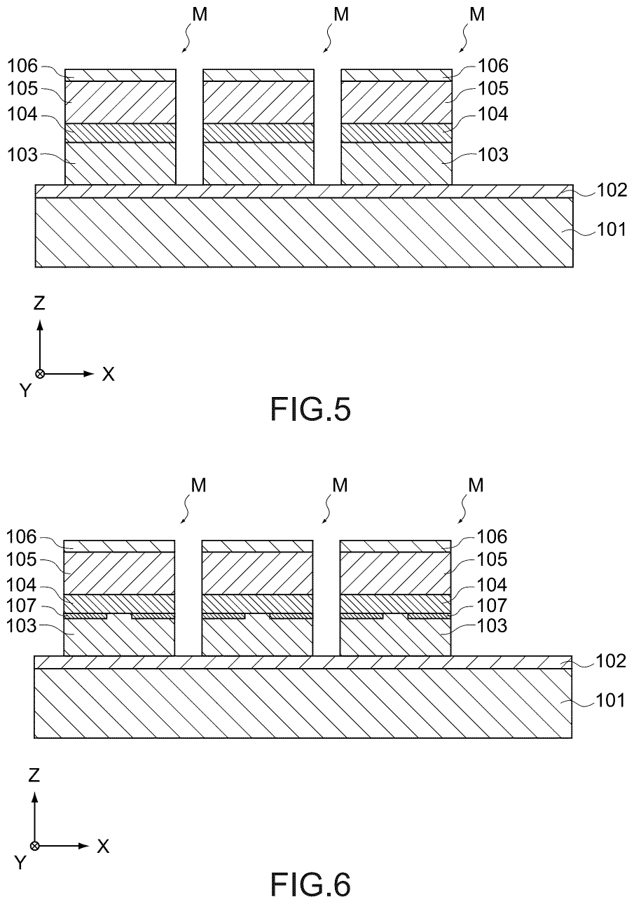

Subsequently, as shown in FIG. 6, the current confinement portion 107 is formed in the first DBR 103. The current confinement portion 107 can be formed by a wet oxidation method in which water vapor is supplied to the periphery of the mesa structure M. The current confinement portion 107 is formed by selectively causing an oxidation reaction in a layer having a high Al composition.

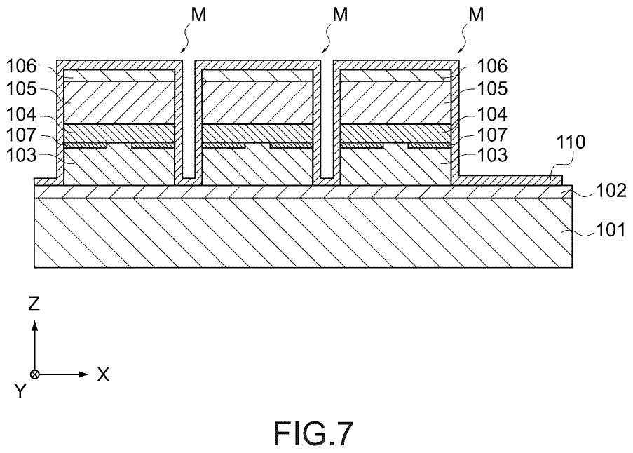

Subsequently, as shown in FIG. 7, the dielectric film 110 is formed on the substrate 101 and around the mesa structure M. The dielectric film 110 can be formed by a chemical vapor deposition (CVD) method. Subsequently, an opening is formed in the dielectric film 110 on the first contact layer 102 and the second contact layer 106. This opening can be formed by RIE or the like. Finaly, as shown in FIG. 3, the first electrode 108 is formed on the first contact layer 102, and the second electrode 109 is formed on the second contact layer 106.

The VCSEL device array 150 can be prepared by the production method as described above. Further, the VCSEL device 100 can also be prepared by the same production method.

### [Regarding Front-Emitting VCSEL Device]

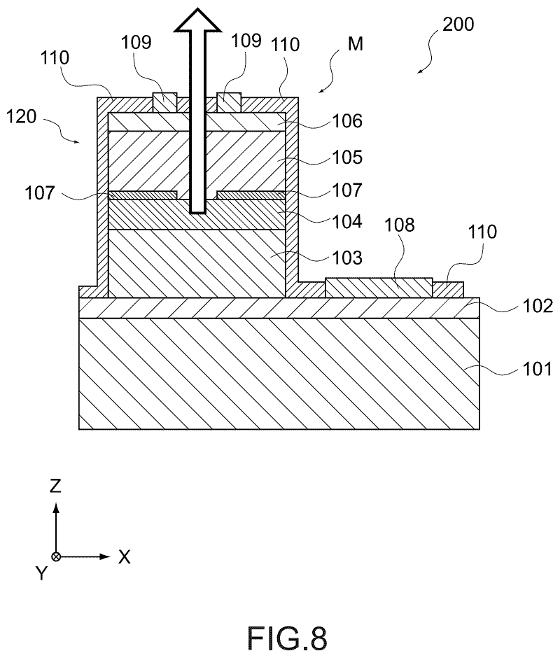

Although the VCSEL device 100 is a back-emitting VCSEL device in the above description, the VCSEL device according to this embodiment may be a front-emitting VCSEL device. FIG. 8 is a schematic diagram of a front-emitting VCSEL device 200. Since each configuration of the VCSEL device 200 is the same as that of the VCSEL device 100 except for a few, the same reference symbols as those in the VCSEL device 100 are given and description thereof is omitted.

The differences from the VCSEL device 100 are that the current confinement portion 107 is provided in the second DBR 105 and that the second electrode 109 has an annular shape surrounding the center of the mesa structure M. As shown in FIG. 8, the laser beam L is transmitted from the active region 104 through the second DBR 105, passes through the ring of the second electrode 109, and is emitted. That is, the laser beam L travels from the light-emitting unit 120 to the side opposite to the substrate 101 and is emitted on the side opposite to the substrate 101. The VCSEL device in which a laser beam is emitted on the side opposite to the substrate in this way is referred to as a front-emitting VCSEL device.

By forming the substrate 101 of the substrate material that is InₓGa₁₋ₓAs (x is 0.005 or more and 0.015 or less) and has a carrier concentration of less than 5×10¹⁷/cm³ in the VCSEL device 200, similarly to the VCSEL device 100, it is possible to reduce the crystal defect density of the substrate 101 and obtain a VCSEL device having high reliability. Further, by setting the lattice constant of the substrate material to a value between the lattice constant of GaAs and the lattice constant of AlAs, it is possible to reduce the warpage of the epitaxial wafer in the process of producing the VCSEL device 200 and improve the productivity.

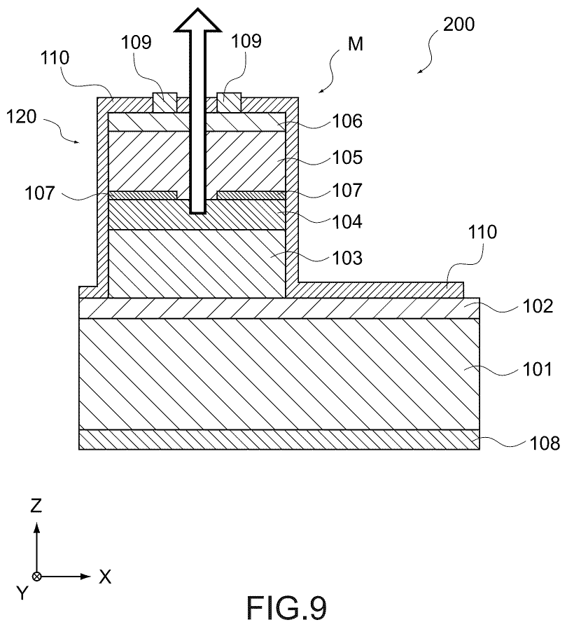

Further, FIG. 9 is a cross-sectional view showing another configuration of the VCSEL device 200. In the VCSEL device 200, since the laser beam L is not transmitted through the substrate 101, the carrier concentration of the substrate material can be made higher. In this case, since the substrate 101 has conductivity, the first electrode 108 can be formed on the back surface of the substrate 101, as shown in FIG. 9.

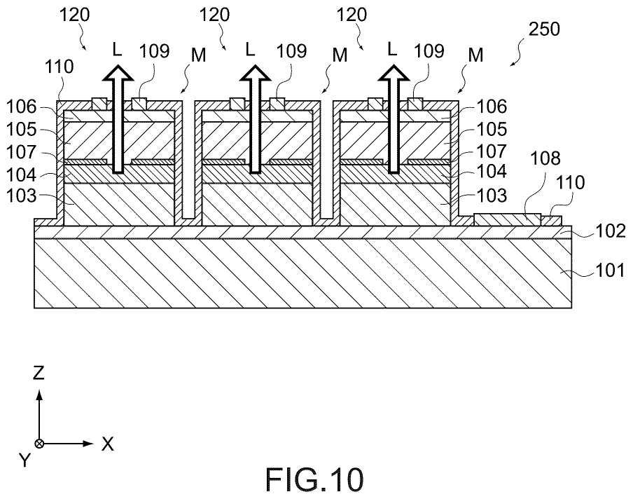

The VCSEL device 200 may also form an array. FIG. 10 is a cross-sectional view of a VCSEL device array 250 according to this embodiment. As shown in the figure, the VCSEL device array 250 includes one substrate 101 and the plurality of light-emitting units 120 formed thereon. The configurations of the substrate 101 and the light-emitting unit 120 are the same as those in the VCSEL device 200, and the laser beam L is emitted on the side opposite to the substrate 101 from each light-emitting unit 120. The number and arrangement of the light-emitting units 120 are not particularly limited, and a one-dimensional array or a two-dimensional array may be used. The VCSEL device array 250 also provides the same effects as those of the VCSEL device 200. Further, also in the VCSEL device array 250, the first electrode 108 may be formed on the back surface of the substrate 101, as shown in FIG. 9.

### [Regarding Present Disclosure]

The effects described in the present disclosure are merely examples and are not limited, and other effects may be achieved. The above description of the plurality of effects does not necessarily mean that these effects are exhibited simultaneously. It means that at least one of the effects described above can be achieved in accordance with the conditions or the like, and there is a possibility that an effect that is not described in the present disclosure is exhibited. Further, at least two feature portions of the feature portions described in the present disclosure may be combined.

Note that the present technology may also take the following configurations.
(1) A vertical cavity surface emitting laser device, including:
   a substrate that is formed of InₓGa₁₋ₓAs (x is 0.005 or more and 0.015 or less) and has a carrier concentration of less than 5×10¹⁷/cm³; and
   a light-emitting unit that includes a first distributed Bragg reflector (DBR) that is formed on the substrate and reflects light having a specific wavelength, a second DBR that reflects light having the wavelength, and an active region that is disposed between the first DBR and the second DBR and generates light emission due to carrier recombination.
(2) The vertical cavity surface emitting laser device according to (1) above, in which
   a lattice constant of the substrate is a value between a lattice constant of GaAs and a lattice constant of AlAs.
(3) The vertical cavity surface emitting laser device according to (1) or (2) above, in which the lattice constant of the substrate is larger than 5.6533 Å and smaller than 5.6605 Å.
(4) The vertical cavity surface emitting laser device according to any one of (1) to (3) above, in which
   the first DBR and the second DBR are each formed of n-type or p-type AlGaAs, and
   the active region includes an active layer formed of InGaAs.
(5) The vertical cavity surface emitting laser device according to any one of (1) to (4) above, which is a back-emitting device in which a laser beam travels from the light-emitting unit to a side of the substrate, is transmitted through the substrate, and is emitted.
(6) The vertical cavity surface emitting laser device according to any one of (1) to (4) above, which is a front-emitting device in which a laser beam travels from the light-emitting unit to a side opposite to the substrate and is emitted on the side opposite to the substrate.
(7) The vertical cavity surface emitting laser device according to any one of (1) to (6) above, in which
   the light-emitting unit includes electrodes disposed such that a current is injected into the active region without passing through the substrate.
(8) The vertical cavity surface emitting laser device according to (7) above, in which
   the light-emitting unit includes a first contact layer that abuts on the first DBR and a second contact layer that abuts on the second DBR, and the pair of electrodes includes a first electrode provided on the first contact layer and a second electrode provided on the second contact layer.
(9) A vertical cavity surface emitting laser device array, including:
   a substrate that is formed of InₓGa₁₋ₓAs (x is 0.005 or more and 0.015 or less) and has a carrier concentration of less than 5×10¹⁷/cm³; and
   a plurality of light-emitting units that is formed on the substrate, each of the light-emitting units including a first distributed Bragg reflector (DBR) that reflects light having a specific wavelength, a second DBR that reflects light having the wavelength, and an active region that is disposed between the first DBR and the second DBR and generates light emission due to carrier recombination.

### REFERENCE SIGNS LIST

100, 200 VCSEL device
101 substrate
102 first contact layer
103 first DBR
104 active region
105 second DBR
106 second contact layer
107 current confinement portion
108 first electrode
109 second electrode
110 dielectric film
120 light-emitting unit
150, 250 VCSEL device array

1. A vertical cavity surface emitting laser device, comprising:
a substrate that is formed of InₓGa₁₋ₓAs (x is 0.005 or more and 0.015 or less) and has a carrier concentration of less than 5×10¹⁷/cm³; and
a light-emitting unit that includes a first distributed Bragg reflector (DBR) that is formed on the substrate and reflects light having a specific wavelength, a second DBR that reflects light having the wavelength, and an active region that is disposed between the first DBR and the second DBR and generates light emission due to carrier recombination.

2. The vertical cavity surface emitting laser device according to claim 1, wherein
a lattice constant of the substrate is a value between a lattice constant of GaAs and a lattice constant of AlAs.

3. The vertical cavity surface emitting laser device according to claim 2, wherein
the lattice constant of the substrate is larger than 5.6533 Å and smaller than 5.6605 Å.

4. The vertical cavity surface emitting laser device according to claim 1, wherein
the first DBR and the second DBR are each formed of n-type or p-type AlGaAs, and
the active region includes an active layer formed of InGaAs.

5. The vertical cavity surface emitting laser device according to claim 1, which is a back-emitting device in which a laser beam travels from the light-emitting unit to a side of the substrate, is transmitted through the substrate, and is emitted.

6. The vertical cavity surface emitting laser device according to claim 1, which is a front-emitting device in which a laser beam travels from the light-emitting unit to a side opposite to the substrate and is emitted on the side opposite to the substrate.

7. The vertical cavity surface emitting laser device according to claim 1, wherein
the light-emitting unit includes a pair of electrodes disposed such that a current is injected into the active region without passing through the substrate.

8. The vertical cavity surface emitting laser device according to claim 7, wherein
the light-emitting unit includes a first contact layer that abuts on the first DBR and a second contact layer that abuts on the second DBR, and the pair of electrodes includes a first electrode provided on the first contact layer and a second electrode provided on the second contact layer.

9. A vertical cavity surface emitting laser device array, comprising:
a substrate that is formed of InₓGa₁₋ₓAs (x is 0.005 or more and 0.015 or less) and has a carrier concentration of less than 5×10¹⁷/cm³; and
a plurality of light-emitting units that is formed on the substrate, each of the light-emitting units including a first distributed Bragg reflector (DBR) that reflects light having a specific wavelength, a second DBR that reflects light having the wavelength, and an active region that is disposed between the first DBR and the second DBR and generates light emission due to carrier recombination.
